(19) United States
(12) Patent Application Publication
(10) Pub. No.: US 2026/0134186 A1
(43) Pub. Date: May 14, 2026

(54) GENERATING A COMPACT CELL LAYOUT

(71) Applicant: International Business Machines Corporation, Armonk, NY (US)

(72) Inventors: Tai Anh Cao, Austin, TX (US); Tobias Werner, Weil im Schoenbuch (DE); Iris Maria Leefken, Dettenhausen (DE); Jean Gibson Gorman, Austin, TX (US)

(21) Appl. No.: 19/055,925

(22) Filed: Feb. 18, 2025

(30) Foreign Application Priority Data
Nov. 14, 2024 (GB) 2416739.7

(51) Int. Cl. G06F 30/392

(52) U.S. Cl. CPC G06F 30/392

(57) ABSTRACT

A computer implemented method for generating a compact cell layout, wherein a standard cell layout has regions of a first type for field effect transistors of a first type and regions of a second type for field effect transistors of a second type, the regions of the first type and the second type being arranged alternatingly in an axial direction, the method comprising providing a schematic; identifying in the schematic at least one field effect transistor of the first type; translating the identified at least one field effect transistor into at least one temporary field effect transistor of the second type; running a standard cell layout generator; translating the at least one temporary field effect transistor of the second type in the standard cell layout back into at least one field effect transistor of the first type in the compact cell layout.

The present invention relates in general to a computer implemented method for generating a compact cell layout, a semiconductor layout, a computer system, a computer program product and a data processing system.

### BACKGROUND

Cells are functional units at the lowest level in a hierarchical design of complex semiconductor chips. A cell may be a logical circuit and comprises a small number of transistors, in particular field effect transistors.

In the design of semiconductor chips, standard cells with certain functions are repeated to be used many times at different places throughout the chip. Accordingly, those standard cells are predesigned and packed in a cell library. The cell library is provided to the chip designers for their particular designs. During chip design, the standard cells are retrieved from the cell libraries and placed into desired locations, thus reducing the design effort because existing modular cells are used. Routing is then performed to connect the standard cells and other circuit blocks to form the desired chip.

US 2024/0113097 A1 discloses an integrated circuit (IC) that has a design layout incorporated with various standard cells. The standard cells are predesigned IC structure to be repeatedly used in individual IC designs. Effective IC design layouts include various predesigned standard cells and predefined rules of placing those standard cells for enhanced circuit performing and reduced circuit areas. The standard cells include inverter, NAND, NOR, AND, OR, XOR, XNOR, local clock buffers, and latches.

US 2023/0369308 A1 discloses a circuit including a first and second active region, spaced along a direction in a first standard cell. Beside the normal features of a standard cell like active gates and dummy (dielectric) gates, containing both NFET (n-type field effect transistor) and PFET (p-type field effect transistor) devices, the disclosure mentions about mixing standard cells of different cell sizes in the same layout flow.

U.S. Pat. No. 12,035,518 B2 relates to semiconductor devices, and more particularly to field-effect transistors (FETs), such as three-dimensional fin-line FETs (FinFETs) or multi-channel gate-all-around (GAA) devices, or even planar FETs. The disclosure involves reconfiguring the N-well and P-well pickup regions, such that a first plurality of small and interleaving N-well and P-well pickup regions are reconfigured into a much bigger continuous N-well pickup region, and a second plurality of small and interleaving N-well and P-well pickup regions are reconfigured into a much bigger continuous P-well pickup region.

### SUMMARY

A computer implemented method for generating a compact cell layout is proposed, wherein a standard cell layout has regions of a first type for field effect transistors of a first type and regions of a second type for field effect transistors of a second type, the regions of the first type and the second type being arranged alternatingly in an axial direction, the method comprising providing a schematic comprising the field effect transistors of the first type and the field effect transistors of the second type; identifying in the schematic at least one field effect transistor of the first type to be moved into one of the regions of the second type, that in the standard cell layout is dedicated to field effect transistors of the second-type; translating the identified at least one field effect transistor of the first type into at least one temporary field effect transistor of the second type; running a standard cell layout generator to generate the standard cell layout using a netlist; translating the at least one temporary field effect transistor of the second type in the standard cell layout back into at least one field effect transistor of the first type in the compact cell layout; adapting the region around the at least one translated field effect transistor of the first type into a region of the first type in the compact cell layout.

The proposed method is about an automatic layout process of a semiconductor chip. This includes a complete system where a designer can enter a schematic (circuit diagram) of small cells with intended parameters and the tools can build a compact layout automatically according to given design rules.

Leaf cells could consist of multiple circuit rows. Every circuitry usually has a dedicated region with default circuit rows for an NFET (or field effect transistor of the first type) and a dedicated region with default circuit rows for a PFET (or field effect transistor of the second type). PFETs can only be placed in in the PFET region and NFETs in the NFET region. If a schematic topology has a lot more NFET devices as PFET devices (or vice versa) there is a lot of area in the PFET region that is unused and the size of the transistor layout is basically dominated by the NFETs that need to be placed in the NFET regions. This results in an inefficient area use. In order to compact the layout, regions that are usually dedicated to PFETs are transformed into areas for NFET.

A “standard cell layout generator” assumes that every circuit row consists of an N-region and a P-region. In order to use a standard cell layout generator for n-dominated or p-dominated layouts and produce the most compact layout dedicated NFETs should look like PFETs in the input of the tool. These NFETs are registered in a netlist as an input to the standard cell layout generator.

In case there are more first type devices, e.g. NFETs, than second type devices, e.g. PFETs, in the provided schematic, and similarly, in the case there are more PFET devices than NFET devices in the provided schematic, NFET devices are intentionally being placed in default circuit rows of PFET devices. This is done automatically by a standard cell layout tool flow process comprising a modification of the netlist, using the standard cell layout generator followed by a modification of the cell layout.

Similarly, in a particular circuit row of a standard cell image that is for both NFET and PFET devices, PFET devices are intentionally being placed in default circuit rows of NFET devices. This is done automatically by the standard cell layout tool flow process. Therefore it is important to first introduce the regions in a circuit row.

A script to convert that standard cell image of NFET/PFET into a layout that is suitable for NFET only in case NFET is placed in the reserved PFET region may advantageously be used for controlling processes of the standard cell layout generator. The region now is connected to ground only. There is no supply voltage contact.

Similarly, a script to convert that standard cell image of NFET/PFET into a layout that is suitable for PFET only in case PFET is placed in the reserved NFET region. The region now is connected to a supply voltage only. There is no ground contact.

The standard cell layout tool flow process can be done in different ways:

By a modular approach which enables the tool flow process one may come to a solution for the smaller parts faster.

By a whole cell approach wherein the tool now can handle the cell as a whole the designer does not have to break the cell into smaller parts. This approach is taking more time than the modular approach.

Both, the modular approach or the whole cell approach, may be performed by modifying the netlist or the schematic.

In the schematic approach a temporary/transitional schematic is modified by converting the NFET devices that should be placed in the reserved p-type regions into PFET devices. Thus, the schematic approach could be applied in the modular approach or in the whole cell approach.

In case of a PFET-dominated cell a similar approach can be applied by modifying a temporary/transitional schematic by converting the PFET devices that should be placed in the reserved n-type regions into NFET devices.

The proposed method advantageously allows automatically building the compact layout of small cells.

In case of a NFET-dominated cell, the empty reserved p-type regions are modified to place NFET devices.

Similarly in case of a PFET-dominated cell, the empty reserved n-type regions are modified to place PFET devices.

The compact layout enables saving area, hence saving power and improving timing of the semiconductor chip. For instance, cells with a given number of rows which have a certain width at the begin of the design process may have a reduced width with the same number of rows in the compact design at the end of the process. Advantageously, the area necessary for the cell layout may be reduced.

In an additional or alternative embodiment of the invention, the first-type may be an n-type and the second type may be a p-type. The method advantageously may be applied to a cell layout of NFET-dominated cells which is quite common in so-called domino circuits.

In an additional or alternative embodiment of the invention, the first type may be a p-type and the second type may be an n-type. The method advantageously may be applied to a cell layout of PFET-dominated cells.

In an additional or alternative embodiment of the invention, the first type to be an n-type or a p-type may be determined based on a majority of a type of the field effect transistors in the schematic used as input to the generation of the cell layout. Thus, for e.g. NFET-dominated cells n-type field effect transistors may be placed in regions which are usually dedicated to p-type field effect transistors.

In an additional or alternative embodiment of the invention, identifying at least one field effect transistor of the first type to be moved into a region of the second type, that in the standard cell layout is dedicated to a field effect transistor of the second type may be decided upon a relative ratio of a number of field effect transistors of the first type to a number of field effect transistors of the second type. Advantageously, transistors may evenly be distributed over the layout image thus saving area on the semiconductor chip.

In an additional or alternative embodiment of the invention, the identified at least one field effect transistor of the first type may be registered in the netlist which is used as an input by the standard cell layout generator. This enables for an automatic cell layout generation by the standard cell layout generator.

In an additional or alternative embodiment of the invention, constraints and/or technology information may be used by the standard cell layout generator during generation of the standard cell layout.

In an additional or alternative embodiment of the invention, regions of the first type may be combined to form a larger region of the first type in the compact cell layout. By this way, compact and efficient usage of the cell area by the field effect transistors of the first type may be enabled.

In an additional or alternative embodiment of the invention, a power line in the compact cell layout may be adapted according to the type of the region adapted. Proper electric supply by the supply voltage as well as by the ground may be achieved.

In an additional or alternative embodiment of the invention, in a modular approach a cell of the standard cell layout may be divided into at least two subcells, a first subcell comprising field effect transistors of the first-type and field effect transistors of the second type and a second subcell comprising only field effect transistors of the first type in the compact cell layout. The at least two subcells may be connected to form the single cell in the cell layout. Electrical interfaces between subcells may be aligned for connecting wires to be lined up for easy connection.

Advantages of the modular approach that smaller subcells may be used, Hence the standard cell layout generator can build the layout faster. The at least two smaller subcells can be run by the standard cell layout generator simultaneously. It is easier to run the converting script to convert a PFET region into an NFET region. And the script only needs to be run on one subcell that contains the only the NFET devices. There is no need to check for wrongly moving the NFET devices in the reserved PFET region. NFET devices may be grouped together into the subcell that are electrically close connected.

In an additional or alternative embodiment of the invention, in a whole cell approach the field effect transistors of the second type are placed in a region of the second type reserved for field effect transistors of the second type only in an outer circuit row, wherein field effect transistors of the first type are placed in circuit rows other than the outer circuit row in regions of the first type and/or the second type. An outer circuit row in this sense may be a top circuit row or a bottom circuit row. The advantage is that the cell does not have to be broken into at least two smaller subcells.

In an additional or alternative embodiment of the invention, in a schematic approach the identified at least one field effect transistor of the first type may be translated into at least one temporary field effect transistor of the second type in the schematic instead of in the netlist, wherein the schematic is used as a temporary schematic. Identifying devices directly in the electrical schematic topology may provide a more intuitive way than changing devices in a netlist. Advantageously the schematic approach may be combined with the modular approach as well as with the whole cell approach by generating a netlist from the temporary schematic instead of using a netlist generated from the original schematics.

In an additional or alternative embodiment of the invention, for translating a cell of the standard cell layout implemented in a single circuit row, the method may further comprise translating all temporary field effect transistors of the second type back to field effect transistors of the first type in the compact cell layout; swapping all pins and/or labels and/or electrical connection of the field effect transistors of the first type from a first power line to a second power line, in particular a ground line; translating all shapes of the second type to shapes of the first type; deleting the first power line.

In an additional or alternative embodiment of the invention, for translating a cell of the standard cell layout implemented in multiple circuit rows, wherein field effect transistors of the first type of an entire circuit row are translated, the method may further comprise providing a list of field effect transistors that are translated; prechecking for all circuit rows if all field effect transistors of a given circuit row are translated or are not translated or part of the field effect transistors are translated; if part of the field effect transistors are translated, then aborting the translation process; if all field effect transistors of a given circuit row are translated, then translating all temporary field effect transistors of the second type back to field effect transistors of the first type in the compact cell layout; swapping all pins and/or labels and/or electrical connection of the field effect transistors of the first type from a first power line to a second power line, in particular a ground line; translating all shapes of the second type to shapes of the first type; deleting the first power line.

In an additional or alternative embodiment of the invention, electrical interfaces between the field effect transistors are aligned in order to minimize a connecting wire length. An efficient compact design of the semiconductor chip may be achieved by minimizing the wire length of the connecting wires.

Further, a semiconductor layout with a compact cell layout generated by the method described above is proposed, wherein an isolated region of a single circuit row of a standard cell layout is translated into a single region of a first type in a cell layout.

In case there are more first type devices, e.g. NFETs, in the semiconductor layout than second type devices, e.g. PFETs, in the provided schematic, and similarly, in the case are more PFET devices than NFET devices in the provided schematic, in a particular circuit row of a standard cell image that is for both NFET and PFET devices, NFET devices are intentionally being placed in the place that is normally reserved for PFET devices. This may be done automatically by a standard cell layout tool flow process. Therefore it is important to first introduce the regions in a circuit row.

Similarly, in a particular circuit row of a standard cell image that is for both NFET and PFET devices, PFET devices are intentionally being placed in the place that is normally reserved for NFET devices. This may be done automatically by the standard cell layout tool flow process. Therefore it is important to first introduce the regions in a circuit row.

The compact semiconductor layout enables saving area, hence saving power and improving timing of the semiconductor chip.

In an additional or alternative embodiment of the invention, the region of the first type may be an n-type region or a p-type region, depending on a majority of a type of field effect transistors in a schematic used as input to the generation of the compact cell layout. Thus, for e.g. NFET-dominated cells n-type field effect transistors may be placed in regions which are usually dedicated to p-type field effect transistors.

Further, a computer system for generating a compact cell layout is proposed, wherein a standard cell layout has regions of a first type for field effect transistors of a first type and regions of a second type for field effect transistors of a second type, the regions of the first type and the second type being arranged alternatingly in an axial direction, comprising a computer processing unit storing computer executable instructions to perform the method described above, comprising: providing a schematic comprising the field effect transistors of the first type and the field effect transistors of the second type; identifying in the schematic at least one field effect transistor of the first type to be moved into one of the regions of the second type, that in the standard cell layout is dedicated to field effect transistors of the second-type; translating the identified at least one field effect transistor of the first type into at least one temporary field effect transistor of the second type; running a standard cell layout generator to generate the standard cell layout using a netlist; translating the at least one temporary field effect transistor of the second type in the standard cell layout back into at least one field effect transistor of the first type in the compact cell layout; adapting the region around the at least one translated field effect transistor of the first type into a region of the first type in the compact cell layout.

The proposed computer system may advantageously be used for a semiconductor chip design process as described above.

Further, a computer program product for generating a compact cell layout is proposed, wherein a standard cell layout has regions of a first type for field effect transistors of a first type and regions of a second type for field effect transistors of a second type, the regions of the first type and the second type being arranged alternatingly in an axial direction, the computer program product comprising a computer readable storage medium having program instructions embodied therewith, the program instructions executable by the computer system to cause the computer system to perform the method described above comprising: providing a schematic comprising the field effect transistors of the first type and the field effect transistors of the second type; identifying in the schematic at least one field effect transistor of the first type to be moved into one of the regions of the second type, that in the standard cell layout is dedicated to field effect transistors of the second-type; translating the identified at least one field effect transistor of the first type into at least one temporary field effect transistor of the second type; running a standard cell layout generator to generate the standard cell layout using a netlist; translating the at least one temporary field effect transistor of the second type in the standard cell layout back into at least one field effect transistor of the first type in the compact cell layout; adapting the region around the at least one translated field effect transistor of the first type into a region of the first type in the compact cell layout.

The proposed computer program product may advantageously be used for a semiconductor chip design process as described above.

Further, a data processing system for execution of a data processing program comprising computer readable program instructions for performing the method is proposed.

The proposed data processing system may advantageously be used for a semiconductor chip design process as described above.

### BRIEF DESCRIPTION OF THE SEVERAL VIEWS OF THE DRAWINGS

The present invention together with the above-mentioned and other objects and advantages may best be understood from the following detailed description of the embodiments, but not restricted to the embodiments.

FIG. 1 depicts a standard cell layout with field effect transistors of a first type and a second type placed in alternating regions of a first type and a second type according to prior art.

FIG. 2 depicts an overview of generating a compact cell layout according to an embodiment of the invention.

FIG. 3 depicts a temporary layout with alternating regions of the first type and the second type and a compact cell layout after translating the temporary field effect transistors of the second type back to field effect transistors of the first type in the compact cell layout and adapting the region around the translated field effect transistors of the first type into a region of the first type in the compact cell layout according to an embodiment of the invention.

FIG. 4 depicts a modular approach for generating the compact cell layout according to an embodiment of the invention.

FIG. 5 depicts a flow chart of the modular approach for generating the compact cell layout according to an embodiment of the invention.

FIG. 6 depicts a flow chart of a whole cell approach for generating the compact cell layout according to an embodiment of the invention.

FIG. 7 depicts an overview of generating a compact cell layout according to a further embodiment of the invention in a schematic approach.

FIG. 8 depicts a flow chart of the schematic approach for generating the compact cell layout according to FIG. 7.

FIG. 9 depicts a flow chart of a single row handling for generating the compact cell layout according to an embodiment of the invention.

FIG. 10 depicts a flow chart of a multi row handling for generating the compact cell layout according to an embodiment of the invention.

FIG. 11 depicts an example embodiment of a data processing system for executing a method according to the invention.

### DETAILED DESCRIPTION

In the drawings, like elements are referred to with equal reference numerals. The drawings are merely schematic representations, not intended to portray specific parameters of the invention. Moreover, the drawings are intended to depict only typical embodiments of the invention and therefore should not be considered as limiting the scope of the invention.

The illustrative embodiments described herein provide a computer implemented method for generating a compact cell layout is proposed, wherein a standard cell layout has regions of a first type for field effect transistors of a first type and regions of a second type for field effect transistors of a second type, the regions of the first type and the second type being arranged alternatingly in an axial direction, the method comprising providing a schematic comprising the field effect transistors of the first type and the field effect transistors of the second type; identifying in the schematic at least one field effect transistor of the first type to be moved into one of the regions of the second type, that in the standard cell layout is dedicated to field effect transistors of the second-type; translating the identified at least one field effect transistor of the first type into at least one temporary field effect transistor of the second type; running a standard cell layout generator to generate the standard cell layout using a netlist; translating the at least one temporary field effect transistor of the second type in the standard cell layout back into at least one field effect transistor of the first type in the compact cell layout; adapting the region around the at least one translated field effect transistor of the first type into a region of the first type in the compact cell layout.

The illustrative embodiments may further be used for a semiconductor layout with a compact cell layout generated by the method described above is proposed, wherein an isolated region of a single circuit row of a standard cell layout is translated into a single region of a first type in a cell layout.

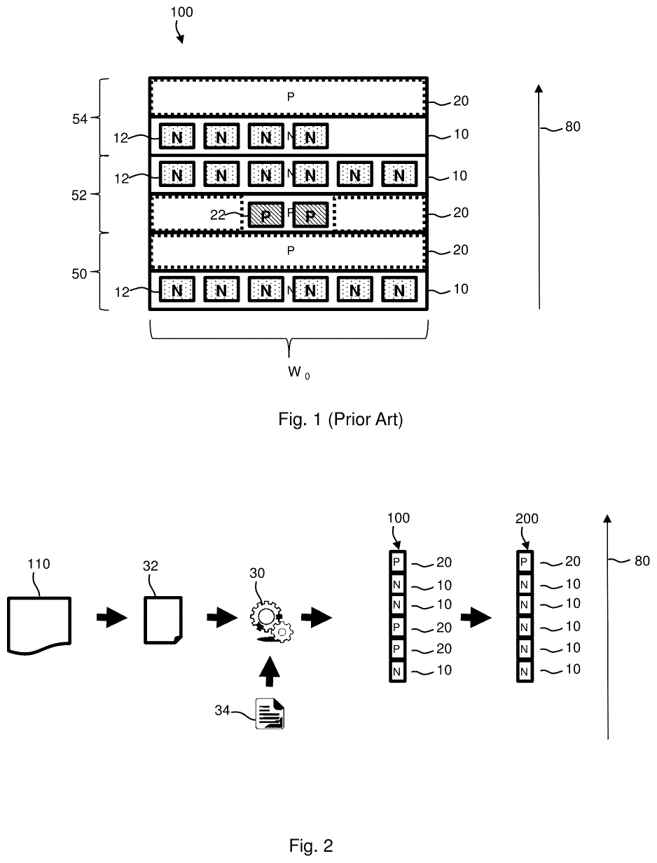

FIG. 1 depicts a standard cell layout 100 according to prior art, where regions 10 of a first type for field effect transistors 12 of a first type and regions 20 of a second type for field effect transistors 22 of a second type are arranged alternatingly in an axial direction 80.

A first region 10 of the first type, an n-type region 10 as is marked by N, is followed by two regions 20 of the second type, a p-type region 20 marked by P, followed by two regions 10 of the first type and another region 20 of the second type.

In a standard layout image two regions 10, 20 are attributed to one circuit row 50, 52, 54. Thus, in FIG. 1 the image is represented by a three circuit rows 50, 52, 54 starting with a circuit row 50, named circuit row zero, from a bottom and extending along the axial direction 80.

In the first row 50, six field effect transistors 12 of the first type, n-type field effect transistors 12 marked by N are placed in the region 10 of the first type. The region 20 of the second type of the first row 50 is empty, followed by region 20 of the second row 52 with only two transistors 22 of the second type, p-type field effect transistors 22 marked by P, followed by region 10 with six field effect transistors 12 of the first type. For instance, the cell width w0 is six transistor widths wide.

The in the third and top row 54, the region 10 contains four field effect transistors 12 of the first type, followed by the region 20 which again is empty.

Boxes with dotted lines represent the empty areas in the layout image. So, there is a lot of wasted space in the prior art layout of the standard cell 100.

FIG. 2 depicts an overview of generating a compact cell layout 200 according to an embodiment of the invention.

First a schematic 110 comprising the field effect transistors 12 of the first type and the field effect transistors 22 of the second type is provided.

Next in the schematic 110 field effect transistors 12 of the first type are identified which could be moved into one of the regions 20 of the second type, that in the standard cell layout 100 is dedicated to field effect transistors 22 of the second-type.

The identified field effect transistors 12 of the first type are registered in a netlist 32 which is used as an input by the standard cell layout generator 30, the netlist 32 thus modified compared to a prior art process.

Identified field effect transistors 12 of the first type are translated into temporary field effect transistors 24 of the second type.

Then, the standard cell layout generator 30 is run to generate the standard cell layout 100 using the modified netlist 32.

Constraints and/or technology information 34 is used by the standard cell layout generator 30 during generation of the cell layout 200.

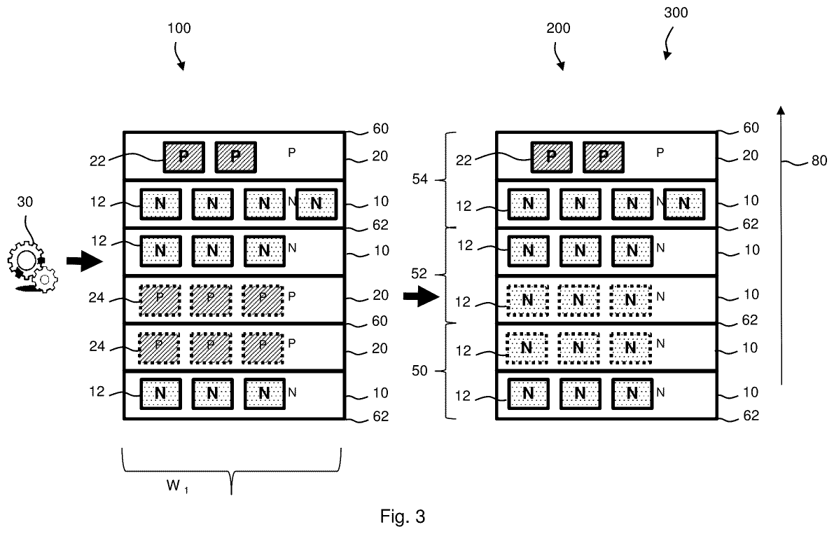

This is shown in the left part of FIG. 3 where a standard layout 100 with alternating regions 10, 20 of the first type and the second type is shown. The temporary field effect transistors 24 of the second type, marked by dotted lines, are located in the regions 20 of the second type.

In FIG. 2 only the regions 10, 20 of the layouts 100, 200 are shown.

Next, the temporary field effect transistors 24 of the second type are translated in the compact cell layout 200 into field effect transistors 12 of the first type.

This is also shown in the right part of FIG. 3 where a compact cell layout 200 after translating the temporary field effect transistors 24 of the second type back to field effect transistors 12 of the first type, marked by dotted lines, is shown.

Next, the regions around the translated field effect transistors 12 of the first type are adapted into regions 10 of the first type in the compact cell layout 200. Thus, regions 10 of the first type are combined to form a larger region of the first type in the compact cell layout 200.

As may be seen in FIG. 3, power lines 60, 62 in the compact cell layout 200 are adapted according to the type of the region 10, 20 adapted. The power line 60 may be e.g. a supply voltage VDD whereas the power line 62 may be e.g. a ground line VSS. While in the example in FIG. 1, where a standard cell layout according to prior art is shown the cell width w0 is six transistor widths wide, now, applying the proposed method, the cell width w1 is only four transistor widths wide. Advantageously, the area necessary for the cell layout may be reduced.

The first-type may be an n-type and the second type may be a p-type. Thus, the field effect transistor 12 of the first type may be an n-type field effect transistor and the field effect transistor 22 of the second type may be a p-type field effect transistor.

Alternatively, the first type may be a p-type and the second type may be an n-type. Thus, the field effect transistor 12 of the first type may be a p-type field effect transistor and the field effect transistor 22 of the second type may be an n-type field effect transistor.

Hereby, determining the first type region 10 to be an n-type or a p-type region 10 is based on a majority of a type of the field effect transistors 12, 22 in the schematic 110 used as input to the generation of the compact cell layout 200. Thus, it is stated if the cell is NFET-dominated or PFET-dominated.

Thus, a decision, if a field effect transistor 12 of the first type may be moved into a region 20 of the second type, that in the standard cell layout 100 is dedicated to a field effect transistor 22 of the second type, may advantageously be made upon a relative ratio of a number of field effect transistors 12 of the first type to a number of field effect transistors 22 of the second type.

Advantageously, by using the described method, a semiconductor layout 300 with a compact cell layout 200 generated by the method may be achieved.

In this semiconductor layout 300, isolated regions 20 of the single circuit rows 50, 52 of the standard cell layout 100 are translated into single regions 10 of a first type in the cell layout 200.

The region 10 of the first type may be an n-type region, as with the embodiment shown, or a p-type region, depending on a majority of a type of field effect transistors 12, 22 in a schematic 110 used as input to the generation of the compact cell layout 200.

The standard cell layout tool flow process can be done in different ways:
By a modular approach which enables the standard cell layout tool flow process a solution for smaller cells may be achieved in a faster way.

By a whole cell approach wherein the standard cell layout tool now can handle the cell as a whole the designer does not have to break the cell into smaller parts. This approach is taking more time than the modular approach.

Both, the modular approach or the whole cell approach, may be performed by modifying the netlist or the schematic.

In the schematic approach a temporary schematic is modified by converting the NFET devices that should be placed in the reserved p-type regions into PFET devices. Thus, the schematic approach could be applied in the modular approach or in the whole cell approach.

In case of a PFET-dominated cell a similar approach can be applied by modifying a temporary schematic by converting the PFET devices that should be placed in the reserved n-type regions into NFET devices.

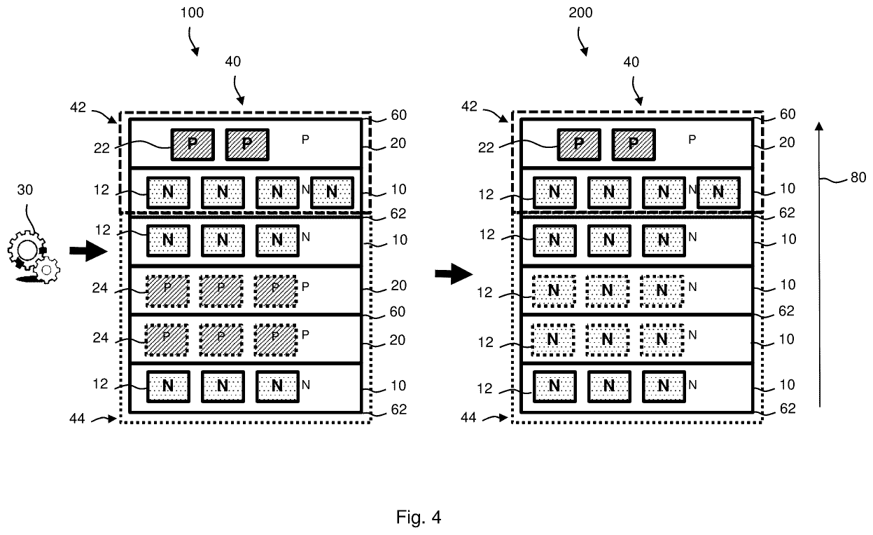

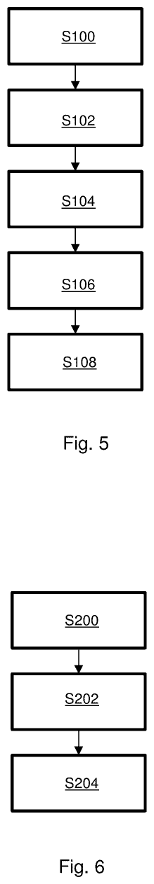

FIG. 4 depicts the modular approach for generating the compact cell layout 200 according to an embodiment of the invention. In FIG. 5 a flow chart of the modular approach for generating the compact cell layout 200 according to an embodiment of the invention is depicted.

In the modular approach, in step S100 the temporary field effect transistors 24 of the second type are identified.

In step S102, the cell 40 of the standard cell layout 100 is divided into at least two subcells 42, 44, marked by boxes with dashed lines and dotted lines, respectively. This is based on the identification of the temporary field effect transistors 24 of the second type in step S100.

In step S104, the temporary field effect transistors 24 of the second type are translated back to field effect transistors 12 of the first type in the compact cell layout 200.

The first subcell 42 then comprises field effect transistors 12 of the first-type and field effect transistors 22 of the second type and the second subcell 44 comprises only field effect transistors 12 of the first type in the compact cell layout 200.

Thus, the first subcell 42 in the compact cell layout 200 comprises “normal” PFET and NFET devices 22, 12. In the embodiment shown in FIG. 4, these are two PFET devices 22 and four NFET devices 12. The standard cell layout generator 30 just uses the “normal” flow for the PFET and NFET devices 22, 12.

The second subcell 44 comprises only NFET devices 12. The standard cell layout generator 30 will put NFET devices 12 in the PFET region 20 according to the modified netlist 32.

For completion of the process, in step S106, the at least two subcells 42, 44 are connected to form the single cell 40 in the compact cell layout 200. Electrical interfaces between subcells 42, 44 may be aligned for connecting wires to be lined up for easy connection of the subcells 42, 44 as well as other cells 40 in step S108.

In modular approach, the cells 40 are divided into two different subcells, the standard image subcell 42 and the subcell 44 with the field effect transistors 12 of the first type only image. Because of this physical separation into at least two subcells 42, 44, it is not necessary to check if NFET devices 12 are put in a reserved PFET region 20. Further, it is not necessary to check which circuit rows 50, 52, 54 the script of the standard cell layout generator 30 is working on.

Electrical interfaces between the field effect transistors 12, 22 may be aligned in order to minimize a connecting wire length connecting the field effect transistors 12, 22 for a compact and efficient design of the cell layout 200.

FIG. 6 depicts a flow chart of the whole cell approach for generating the compact cell layout 200 according to an embodiment of the invention.

In the whole cell approach, in step S200, the field effect transistors 22 of the second type are placed in a region 20 of the second type reserved for field effect transistors 22 of the second type only in an outer circuit row 54. An outer circuit row hereby means the top circuit row 54 or the bottom circuit row 50. Rows 50, 52, 54 are marked in FIG. 3.

In step S202, field effect transistors 12 of the first type are placed in circuit rows 50, 52 in regions 10, 20 of the first type and/or the second type. In outer circuit row 54 field effect transistors 12 of the first type are allowed to be placed only in a region 10 of the first type.

Summarizing, in the whole cell approach the field effect transistors 22 of the second type are placed in a region 20 of the second type reserved for field effect transistors 22 of the second type only in an outer circuit row 54, wherein field effect transistors 12 of the first type are placed in circuit rows 50, 52 other than the outer circuit row 54 in regions 10, 20 of the first type and/or the second type and in the outer circuit row 54 field effect transistors 12 of the first type are placed only in in a region 10 of the first type.

In step S204, a checking process is performed. The standard cell layout generator 30 may advantageously be provided with a safeguard feature that guarantees that no NFET devices 12 are placed in the reserved PFET region 20.

The script controlling the process of the standard cell layout generator 30 that works in the whole cell approach may be provided with a feature to know which circuit rows 50, 52, 54 in the compact layout 200 need to be converted from second type to first type.

As in the whole cell approach, there should be at least one p-type region 20 that is exclusively reserved as a p-type region 20. And that p-type region 20 should be an outer circuit row 50, 52, 54, either at the bottom/top edge of the compact cell layout 200.

In the whole cell approach, some NFET devices 12 are put in the p-type regions 20. These p-type regions 20 are different from the reserved p-type region 20. In that reserved p-type region 20, there should be no NFET devices 12 allowed.

The verification step is to make sure that the NFET devices 12 are not being put in the reserved p-type region 20 by mistake. The verification step may be done manually.

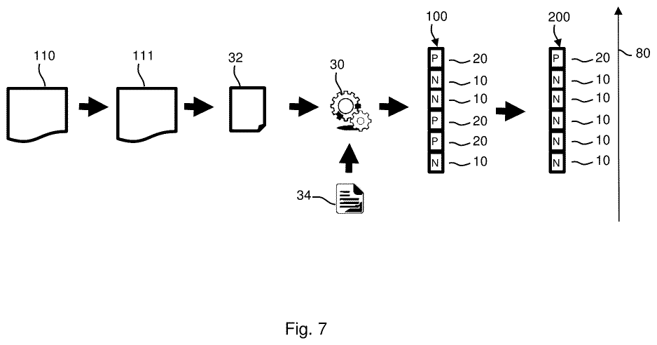

FIG. 7 depicts an overview of generating a compact cell layout 200 according to a further embodiment of the invention in the schematic approach.

Rather than modifying the netlist 32, as is described with the embodiment shown in FIG. 2, in this embodiment the schematic 110 may be modified to a temporary schematic 111, whereas the netlist 32 will look the same in both cases.

In the schematic approach the identified field effect transistors 12 of the first type may be translated into temporary field effect transistors 24 of the second type in the schematic 110 instead of in the netlist 32, this changed schematic 111 is used as a temporary schematic 111 in the process.

In this embodiment the temporary schematic 111 may be used instead of the original schematic 110 for generating the netlist 32 for the standard cell layout generator 30.

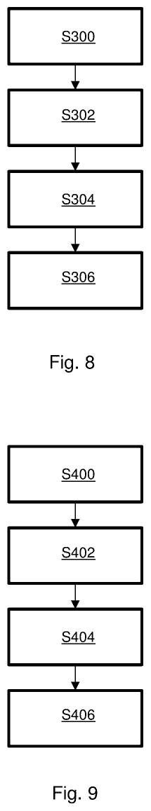

FIG. 8 depicts a flow chart of the schematic approach for generating the compact cell layout 200 according to FIG. 7.

In the schematic approach, first, in step S300, at least one field effect transistor 12 of the first type to be moved into one of the regions 20 of the second type that in the standard cell 100 is dedicated to field effect transistors 22 of the second type is identified in the schematic 110.

Then, in step S302, the identified at least one field effect transistor 12 of the first type is translated into at least one temporary field effect transistor 24 of the second type in the schematic 110 instead of in the netlist 32, wherein the schematic 110 is used as a temporary schematic 111.

In step S304, the cell layout generator 30 is run and finally, in step S306, the at least one temporary field effect transistor 24 of the second type is translated back to the field effect transistor 12 of the first type in the compact cell layout 200.

In the case of using the schematics method which can either be used in the whole cell approach or in the modular approach electrical interfaces between the field effect transistors 12, 22 may be aligned in order to minimize a connecting wire length connecting the field effect transistors 12, 22 for a compact and efficient design of the cell layout 200.

FIG. 9 depicts a flow chart of a single row handling for generating the compact cell layout 200 according to an embodiment of the invention.

For translating a cell 40 of the standard cell layout 100 implemented in a single circuit row 50, 52, 54, first, in step S400, all temporary field effect transistors 24 of the second type is translated back to field effect transistors 12 of the first type in the compact cell layout 200.

Then, in step S402, all pins and/or labels and/or electrical connection of the field effect transistors 12 of the first type are swapped from a first power line 60, in particular a so-called power net, usually VDD, to a second power line 62, in particular a ground line VSS.

Next, in step S404, all shapes of the second type are translated to shapes of the first type. This step may comprise to translate so-called PPLUS shapes into so-called NPLUS shapes, as well as to translate so-called NW shapes and/or pins and/or labels into so-called BSUB or SXCUT shapes and/or pins and/or labels. Further, it may comprise to translate so-called VT shapes from VTP to VTN shapes.

Then, in step S406, the first power line 60 is deleted. The VDD term as well as VDD nets may be deleted.

Thus, layers are efficiently translated from a region 20 of the second type to a region 10 of the first type.

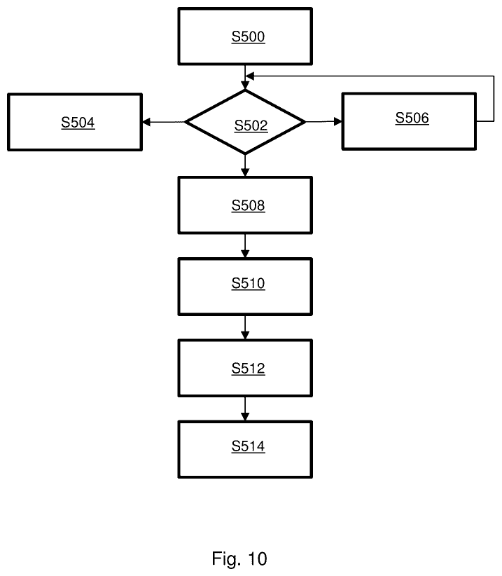

FIG. 10 depicts a flow chart of a multi row handling for generating the compact cell layout 200 according to an embodiment of the invention.

A base assumption of this multi row handling process is that field effect transistors 12 of the first type of an entire circuit row 50, 52, 54 are translated.

For translating a cell 40 of the standard cell layout 100 implemented in multiple circuit rows 50, 52, 54, first, in step S500, a list of field effect transistors 12 that are translated is provided.

Next, in step S502, it is prechecked for all circuit rows 50, 52, 54 if all field effect transistors 12 of a given circuit row 50, 52, 54 are translated or are not translated or only part of the field effect transistors 12 are translated.

If no field effect transistors 12 of a given circuit row 50, 52, 54 are translated, then the translation process in step S506 moves on to the next circuit row 50, 52, 54.

If part of the field effect transistors 12 are translated, then the translation process is aborted in step S504, because only entire circuit rows 50, 52, 54 can be translated.

If all field effect transistors 12 of a given circuit row 50, 52, 54 are translated, then all temporary field effect transistors 24 of the second type are translated back in step S508 to field effect transistors 12 of the first type in the compact cell layout 200.

Then, in step S510, all pins and/or labels and/or electrical connection of the field effect transistors 12 of the first type are swapped from a first power line 60, in particular a so-called power net, usually VDD, to a second power line 62, in particular a ground line VSS.

Next, in step S512, all shapes of the second type are translated to shapes of the first type. This step may comprise to translate so-called PPLUS shapes into so-called NPLUS shapes, as well as to translate so-called NW shapes and/or pins and/or labels into so-called BSUB or SXCUT shapes and/or pins and/or labels. Further, it may comprise to translate so-called VT shapes from VTP to VTN shapes.

Then, in step S514, the first power line 60 is deleted. The VDD term as well as VDD nets may be deleted.

Thus, layers are efficiently translated from a region 20 of the second type to a region 10 of the first type.

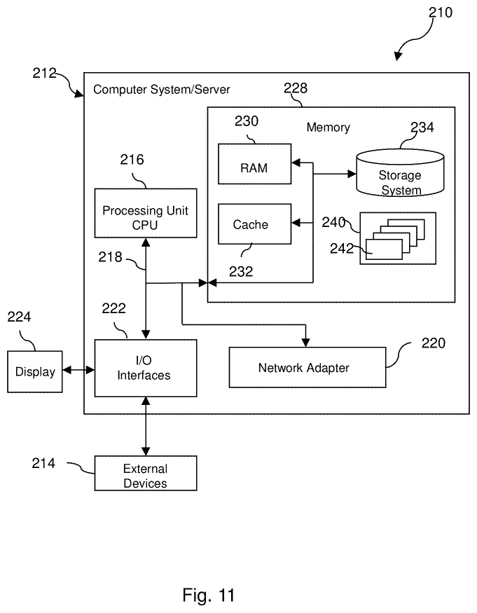

Referring now to FIG. 11, a schematic of an example of a data processing system 210 is shown. Data processing system 210 is only one example of a suitable data processing system and is not intended to suggest any limitation as to the scope of use or functionality of embodiments of the invention described herein. Regardless, data processing system 210 is capable of being implemented and/or performing any of the functionality set forth herein above.

In data processing system 210 there is a computer system/server 212, which is operational with numerous other general-purpose or special-purpose computing system environments or configurations. Examples of well-known computing systems, environments, and/or configurations that may be suitable for use with computer system/server 212 include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 212 may be described in the general context of computer system executable instructions, such as program modules, being executed by a computer system. Generally, program modules may include routines, programs, objects, components, logic, data structures, and so on that perform particular tasks or implement particular abstract data types. Computer system/server 212 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 11, computer system/server 212 in data processing system 210 is shown in the form of a general-purpose computing device. The components of computer system/server 212 may include, but are not limited to, one or more processors or processing units 216, a system memory 228, and a bus 218 that couples various system components including system memory 228 to processor 216.

Bus 218 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer system/server 212 typically includes a variety of computer system readable media. Such media may be any available media that is accessible by computer system/server 212, and it includes both volatile and non-volatile media, removable and non-removable media.

System memory 228 can include computer system readable media in the form of volatile memory, such as random access memory (RAM) 230 and/or cache memory 232. Computer system/server 212 may further include other removable/non-removable, volatile/non-volatile computer system storage media. By way of example only, storage system 234 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 218 by one or more data media interfaces. As will be further depicted and described below, memory 228 may include at least one program product having a set (e.g., at least one) of program modules that are configured to carry out the functions of embodiments of the invention.

Program/utility 240, having a set (at least one) of program modules 242, may be stored in memory 228 by way of example, and not limitation, as well as an operating system, one or more application programs, other program modules, and program data. Each of the operating system, one or more application programs, other program modules, and program data or some combination thereof, may include an implementation of a networking environment. Program modules 242 generally carry out the functions and/or methodologies of embodiments of the invention as described herein.

Computer system/server 212 may also communicate with one or more external devices 214 such as a keyboard, a pointing device, a display 224, etc.; one or more devices that enable a user to interact with computer system/server 212; and/or any devices (e.g., network card, modem, etc.) that enable computer system/server 212 to communicate with one or more other computing devices. Such communication can occur via Input/Output (I/O) interfaces 222. Still yet, computer system/server 212 can communicate with one or more networks such as a local area network (LAN), a general wide area network (WAN), and/or a public network (e.g., the Internet) via network adapter 220. As depicted, network adapter 220 communicates with the other components of computer system/server 212 via bus 218. It should be understood that although not shown, other hardware and/or software components could be used in conjunction with computer system/server 212. Examples, include, but are not limited to: microcode, device drivers, redundant processing units, external disk drive arrays, RAID systems, tape drives, and data archival storage systems, etc.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special-purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special-purpose hardware-based systems that perform the specified functions or acts or carry out combinations of special-purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### REFERENCE NUMERALS

10 region of the first type
12 field effect transistor of the first type
20 region of the second type
22 field effect transistor of the second type
24 temporary field effect transistor of the second type
30 standard cell layout generator
32 netlist
34 constraints and/or technology information
40 cell
42 first subcell
44 second subcell
50 circuit row
52 circuit row
54 circuit row
60 power line VDD
62 power line VSS
80 axial direction
100 standard cell layout
110 schematic
111 temporary schematic
200 cell layout
210 data processing system
212 computer system/server
214 external devices
216 CPU/data processing unit
218 IO Bus
220 network adapter
222 IO interfaces
224 display
228 memory
230 RAM
232 cache
234 storage system
240 program/utility
242 program modules
300 semiconductor layout
w0 cell width at begin of process
w1 cell width at end of process

1. A computer implemented method for generating a compact cell layout, wherein a standard cell layout has regions of a first type for field effect transistors of a first type and regions of a second type for field effect transistors of a second type, the regions of the first type and the second type being arranged alternatingly in an axial direction, the method comprising:
providing a schematic comprising the field effect transistors of the first type and the field effect transistors of the second type;
identifying, in the schematic, at least one field effect transistor of the first type to be moved into one of the regions of the second type, that in the standard cell layout is dedicated to field effect transistors of the second type;
translating the identified at least one field effect transistor of the first type into at least one temporary field effect transistor of the second type;
running a standard cell layout generator to generate the standard cell layout using a netlist;
translating the at least one temporary field effect transistor of the second type in the standard cell layout back into at least one field effect transistor of the first type in the compact cell layout; and
adapting the region around the at least one translated field effect transistor of the first type into a region of the first type in the compact cell layout.

2. The method according to claim 1, wherein the first type is an n-type and the second type is a p-type.

3. The method according to claim 1, wherein the first type is a p-type and the second type is an n-type.

4. The method according to claim 1, wherein determining the first type to be an n-type or a p-type is based on a majority of a type of the field effect transistors in the schematic used as input to the generation of the compact cell layout.

5. The method according to claim 1, wherein identifying at least one field effect transistor of the first type to be moved into a region of the second type, that in the standard cell layout is dedicated to a field effect transistor of the second type is decided upon a relative ratio of a number of field effect transistors of the first type to a number of field effect transistors of the second type.

6. The method according to claim 1, wherein the identified at least one field effect transistor of the first type is registered in the netlist which is used as an input by the standard cell layout generator.

7. The method according to claim 1, wherein constraints and/or technology information is used by the standard cell layout generator during generation of the standard cell layout.

8. The method according to claim 1, wherein regions of the first type are combined to form a larger region of the first type in the compact cell layout.

9. The method according to claim 1, wherein a power line in the compact cell layout is adapted according to the type of the region adapted.

10. The method according to claim 1, wherein in a modular approach a cell of the standard cell layout is divided into at least two subcells, a first subcell comprising field effect transistors of the first type and field effect transistors of the second type and a second subcell comprising only field effect transistors of the first type in the compact cell layout,
wherein the at least two subcells are connected to form a single cell in the compact cell layout,
wherein electrical interfaces between subcells are aligned for connecting wires to be lined up for easy connection.

11. The method according to claim 1, wherein in a whole cell approach the field effect transistors of the second type are placed in a region of the second type reserved for field effect transistors of the second type only in an outer circuit row, wherein field effect transistors of the first type are placed in circuit rows other than the outer circuit row in regions of the first type and/or the second type and in circuit row field effect transistors of the first type are only placed in the regions of the first type.

12. The method according to claim 1, wherein in a schematic approach the identified at least one field effect transistor of the first type is translated into at least one temporary field effect transistor of the second type in the schematic instead of in the netlist, wherein the schematic is used as a temporary schematic.

13. The method according to claim 1, for translating a cell of the standard cell layout implemented in a single circuit row, comprising:
translating all temporary field effect transistors of the second type back to field effect transistors of the first type in the compact cell layout;
swapping all pins and/or labels and/or electrical connection of the field effect transistors of the first type from a first power line to a second power line, in particular a ground line;
translating all shapes of the second type to shapes of the first type; and
deleting the first power line.

14. The method according to claim 1, for translating a cell of the standard cell layout implemented in multiple circuit rows, wherein field effect transistors of the first type of an entire circuit row are translated, comprising:
providing a list of field effect transistors that are translated;
prechecking for all circuit rows if all field effect transistors of a given circuit row are translated or are not translated or part of the field effect transistors are translated;
if part of the field effect transistors are translated, then aborting the translation process; and
if all field effect transistors of a given circuit row are translated, then
translating all temporary field effect transistors of the second type back to field effect transistors of the first type in the compact cell layout;
swapping all pins and/or labels and/or electrical connection of the field effect transistors of the first type from a first power line to a second power line, in particular a ground line;
translating all shapes of the second type to shapes of the first type; and
deleting the first power line.

15. The method according to claim 1, wherein electrical interfaces between the field effect transistors are aligned in order to minimize a connecting wire length.

16. The method according to claim 1, further comprising:
generating a semiconductor layout with a compact cell layout, wherein an isolated region of a single circuit row of a standard cell layout is translated into a single region of a first type in a cell layout.

17. The method according to claim 16, wherein the region of the first type is an n-type region or a p-type region, depending on a majority of a type of field effect transistors in a schematic used as input to the generation of the compact cell layout.

18. A computer system for generating a compact cell layout, wherein a standard cell layout has regions of a first type for field effect transistors of a first type and regions of a second type for field effect transistors of a second type, the regions of the first type and the second type being arranged alternatingly in an axial direction,
comprising a computer processing unit storing computer executable instructions to perform a method, the method comprising:
providing a schematic comprising the field effect transistors of the first type and the field effect transistors of the second type;
identifying, in the schematic, at least one field effect transistor of the first type to be moved into one of the regions of the second type, that in the standard cell layout is dedicated to field effect transistors of the second type;
translating the identified at least one field effect transistor of the first type into at least one temporary field effect transistor of the second type;
running a standard cell layout generator to generate the standard cell layout using a netlist;
translating the at least one temporary field effect transistor of the second type in the standard cell layout back into at least one field effect transistor of the first type in the compact cell layout; and
adapting the region around the at least one translated field effect transistor of the first type into a region of the first type in the compact cell layout.

19. A computer program product for generating a compact cell layout, wherein a standard cell layout has regions of a first type for field effect transistors of a first type and regions of a second type for field effect transistors of a second type, the regions of the first type and the second type being arranged alternatingly in an axial direction,
the computer program product comprising a computer readable storage medium having program instructions embodied therewith, the program instructions executable by a computer system capable of performing a method, the method comprising:
providing a schematic comprising the field effect transistors of the first type and the field effect transistors of the second type;
identifying, in the schematic, at least one field effect transistor of the first type to be moved into one of the regions of the second type, that in the standard cell layout is dedicated to field effect transistors of the second type;
translating the identified at least one field effect transistor of the first type into at least one temporary field effect transistor of the second type;
running a standard cell layout generator to generate the standard cell layout using a netlist;
translating the at least one temporary field effect transistor of the second type in the standard cell layout back into at least one field effect transistor of the first type in the compact cell layout; and
adapting the region around the at least one translated field effect transistor of the first type into a region of the first type in the compact cell layout.

20. The computer program product according to claim 19, further comprising a data processing system for execution of a data processing program.
